(19) United States
(12) Patent Application Publication
(10) Pub. No.: US 2005/0090114 A1
(43) Pub. Date: Apr. 28, 2005

(54) Method for the production of a semiconductor device

(76) Inventors: Michael Rogalli, Rottenburg (DE); Alexander Reb, Dresden (DE); Lars Volkel, Dresden (DE); Maik Stegemann, Dresden (DE)

Correspondence Address: Thomas G Eschweiler;Eschweiler & Associates, National City Bank Building, 629 Euclid Avenue Suite 1210, Cleveland, OH, 44114, US

(21) Appl. No.: 10/493,148

(22) PCT Filed: Oct. 29, 2002
(86) PCT No.: PCT/DE02/04062

(30) Foreign Application Priority Data
Oct. 31, 2001 (DE) 101 54 966.0

(51) Int. Cl. H01L 21/302; H01L 21/461

(52) U.S. Cl. 438/706

(57) ABSTRACT

The invention relates to a process for the production of a semiconductor apparatus, in which an etch step is carried out after an exposure step using light having a wavelength of 193 nm and a development step, the etch gas used containing an added reactive monomer. As a result, polymerization of the surface and hence sidewall passivation of the photoresist used are achieved.

Cost reductions of up to 30% are required annually in the semiconductor business in order still to achieve a profit with the constant price decrease. Traditionally, the necessary cost reduction is obtained by reducing the size of the semiconductor structures, in particular in the memory area.

A reduction in the structure sizes is possible through reducing the wavelength of the light in lithography. At present, the wavelength of the light for DUV exposure (“deep ultraviolet”) is 248 nm. In the next generation, the wavelength will be 193 nm.

Conventional lithography processes generally comprise an exposure step, followed by a development step and an etch step. During etching, the structure produced in the preceding exposure and development steps is transferred to a substrate, for example for producing conductor tracks. For this purpose, the substrate surface is exposed to a plasma which reacts with it and thus removes the material of the unexposed structures.

A general problem in lithography is the production of rough edges in the resist profile. During etching, the resist profile and hence also its rough edges are “adopted”, i.e. reproduced on the layer underneath. Owing to the lack of sidewall passivation, bowing also occurs, i.e. the edges of the resist profile are rounded. Moreover, the resist exhibits damage after the etching.

This problem occurs to a greater extent in 193 nm lithography than in the conventional 248 nm lithography. This is because the resists which have to be used in 193 nm lithography differ from those for the 248 nm lithography. Instead of aromatic components, aliphatic and cycloaliphatic systems are used. In comparison with the aromatic resists, these systems generally have less uniform edge formation and a lower thermal stability.

An obvious countermeasure would be to reduce the cathode temperature during etching. In addition, etch gases which contain fluorine could be used. Such gases generally cause a chemical reaction which can result in sidewall passivation. However, experiments with these countermeasures have been unsuccessful.

It is the object of the present invention at least to reduce the problems described above. This object is achieved by the invention stated in the independent claims. Advantageous embodiments are described in the subclaims.

According to the invention, a process is provided for the production of semiconductor apparatus using a substrate on which a photosensitive layer and a layer to be structured and present underneath are applied, comprising the following steps:
exposure of the photosensitive layer through a mask; development of the exposed photosensitive layer for the formation of masking structures;
selective removal of material of unmasked parts of the layer to be structured, by means of an etch gas which contains a reactive monomer.

The semiconductor substrate may contain additional layers present between or on said layers.

The reactive monomer may be an alkyne, an alkyne derivative, an ethyne or an ethyne derivative.

Furthermore, the process becomes can advantageously be carried out in a lithography process in which the exposure step is used carried out using light having a wavelength of 193 nm.

According to the invention, etch gas is also provided for etching a layer of a semiconductor substrate, which layer is to be structured, in the production of a semiconductor apparatus, the etch gas containing a reactive monomer.

As already mentioned in relation to the process according to the invention, the reactive monomer may be an alkyne, an alkyne derivative, an ethyne, an ethyne derivative, a.

By using a reactive monomer as part of the etch gas or in addition to the etch gas, polymerization (passivation) of the sidewalls of the resist and hence formation of unsaturated structures on the resist surface are achieved. The stated problems of bowing and of the rough edges of the resist are very substantially eliminated. By means of polymerization of an additive in the etch gas (namely of the reactive monomer), the same effect is thus achieved as in the 248 nm lithography by means of the use of an aromatic resist. Thus, chip structures which correspond in quality to those produced by means of 248 nm lithography can now also be produced by 193 nm lithography. Consequently, a further miniaturization and, associated with this, an increase in the cost-efficiency or productivity in chip production are achieved.

The invention will now be explained on the basis of an embodiment with reference to the drawings, in which:

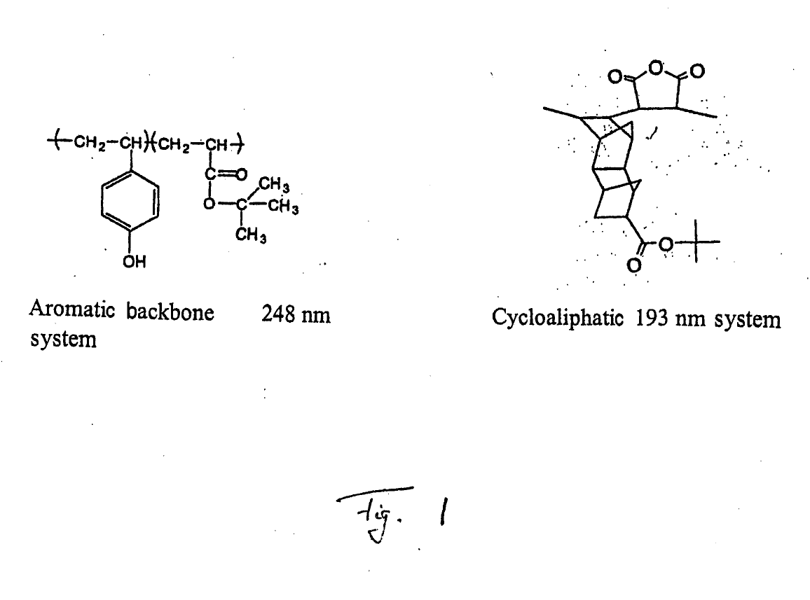

FIG. 1 shows the chemical structures of the resist systems for the 248 nm lithography (left) and the 193 nm lithography (right) and

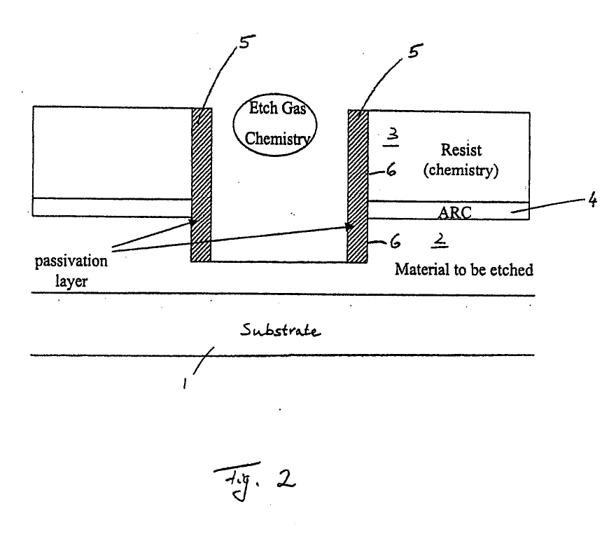

FIG. 2 shows a schematic cross section through the layer structure in the production of a semiconductor apparatus.

FIG. 1 illustrates, on the left, the chemical structure of a resist which is used in 248 nm lithography. On the right is the chemical structure of a resist for 193 nm lithography. In contrast to the 248 nm system, this resist has, as described above, the disadvantage that it does not initiate formation of a passivation layer during etching.

This deficiency is compensated by the etch gas containing an added reactive monomer, such as, for example, an alkyne or an alkyne derivative. As a consequence of this, unsaturated structures are produced on the surface during etching, in analogous manner to the etching of the 248 nm resist. This results in the formation of a passivation layer. By adding reactive monomers to the etch gas, the etch conditions of a 248 nm system are accordingly produced in a 193 nm system.

FIG. 2 schematically shows the layers in the production of a semiconductor apparatus. A layer 2 to be etched is applied to a substrate 1. On top of said layer 2 is a resist layer 3. The resist layer 3 is generally resistant to etching of the layer 2. In addition, an antireflective coat 4 (ARC) is present between the resist layer 3 and the layer 2 to be etched.

FIG. 2 furthermore shows a passivation layer 5 which is formed by polymerization of the reactive monomer. The passivation layer 5 protects the sidewalls 6 of the resist 3 and of the layer 2 to be etched. Consequently, they are protected from isotropic damage.

It should be noted that the invention is not limited to the embodiments described but comprises modifications within the scope of the area of protection specified by the claims.

1. A process for the production of a semiconductor apparatus using a substrate on which a photosensitive layer and a layer to be structured and present underneath are applied, comprising the following steps:
exposure of the photosensitive layer through a mask;
development of the exposed photosensitive layer for the formation of masking structures;
selective removal of material of unmasked parts of the layer to be structured, by means of an etch gas which contains a reactive monomer.

2. The process as claimed in claim 1, the reactive monomer being an alkyne or alkyne derivative.

3. The process as claimed in claim 1, the reactive monomer being an ethyne or ethyne derivative.

4. The process as claimed in claim 1, the reactive monomer being an acetylene or acetylene derivative.

5. The process as claimed in any of the preceding claims, light having a wavelength of 193 nm being used for the exposure.

6. An etch gas for etching a layer to be structured on a substrate in the production of a semiconductor apparatus in a lithography process, the etch gas containing a reactive monomer.

7. The etch gas as claimed in claim 6, the reactive monomer being an alkyne or alkyne derivative.

8. The etch gas as claimed in claim 6, the reactive monomer being an ethyne or ethyne derivative.

9. The etch gas as claimed in claim 6, the reactive monomer being an acetylene or acetylene derivative.
